(19) United States
(12) Patent Application Publication
(10) Pub. No.: US 2015/0303102 A1
(43) Pub. Date: Oct. 22, 2015

(54) SEMICONDUCTOR WAFER WITH NONSTICK SEAL REGION

(71) Applicant: INTERNATIONAL BUSINESS MACHINES CORPORATION, ARMONK, NY (US)

(72) Inventors: Charles L. Arvin, Poughkeepsie, NY (US); Nitin Jadhav, Wappingers Falls, NY (US); Ian D. Melville, Highland, NY (US); Freddie Torres, Beacon, NY (US); Michael D. Webster, Poughkeepsie, NY (US)

(73) Assignee: INTERNATIONAL BUSINESS MACHINES CORPORATION, ARMONK, NY (US)

(21) Appl. No.: 14/258,421

(22) Filed: Apr. 22, 2014

(51) Int. Cl. H01L 21/768; H01L 21/027

(52) U.S. Cl. CPC H01L 21/76873; H01L 21/0273; H01L 21/76885

(57) ABSTRACT

A semiconductor wafer includes a nonstick region. During integrated circuit fabrication processes, the wafer may be inserted into an electrodeposition (e.g. plating, etc.) tool. The tool may contact the nonstick region to e.g. prevent leaks, prevent plating upon a shorting layer of the wafer, etc. When the wafer is removed the nonstick region has a propensity to not transfer to the tool, improving tool availability and reducing wafer scraps. The nonstick region may contain a nonstick seal formed from a liquid photoresist based material, an organic dielectric, etc.

### FIELD

Embodiments of invention generally relate to semiconductor devices, design structures for designing a semiconductor device, or semiconductor device fabrication methods. More particularly, embodiments relate to a semiconductor wafer with a nonstick perimeter seal region.

### BACKGROUND

Formation of integrated circuit structures upon a semiconductor wafer may require photoresist patterning and subsequent electroplating processes. During electroplating, a metal or other electrically conductive material is plated upward from the wafer surface within the openings of the patterned photoresist. Electroplating typically takes place in an electroplating tool. During plating of the semiconductor wafer, the electroplating tool seals against the photoresist to, for example, prevent plating on the wafer's shorting layer where electrical contact is made during the plating operation.

Photoresists are chosen for their properties of defining the pattern. However, it is typical that many of these photoresists adhere to the seal of the electroplating tool. When the wafer is removed from the electroplating tool the photoresist may transfer to the sealing surface of the electroplating tool. A buildup of photoresist material upon the sealing surface may cause inadequate seals for subsequent wafers and may lead to leaks. Further, for thinned wafers supported by a carrier, the edges of the thinned wafer may be removed with the photoresist. Since a typical carrier is made of glass, removal of the thinned wafer appears as holes to any optical sensing devices and can prevent the wafers from being processed further and ultimately would cause the wafer to be scraped. The removed edges of the wafer can also lead to the initiation of a crack that propagates through the thin wafer which also would also cause the wafer to be scrapped.

Current solutions are to accept the propensity of scraps or to clean the electroplating tool at certain intervals. The cleaning leads to tool unavailability and may not effectively stop the formation of defects.

### SUMMARY

In an embodiment of the present invention, a semiconductor wafer fabrication method includes: forming a nonstick seal within a nonstick region and within a non-pattering region of a semiconductor wafer, applying a photoresist upon the semiconductor wafer within one or more active regions and upon the nonstick seal within the non-pattering region, and forming plating structures within the photoresist within the one or more active regions of the semiconductor wafer.

In another embodiment of the present invention, a semiconductor wafer fabrication method includes: forming an organic dielectric upon a semiconductor wafer, removing the organic dielectric within a perimeter edge region of the semiconductor wafer, applying a photoresist upon the organic dielectric, revealing the organic dielectric within a nonstick region of the semiconductor wafer, and forming plating structures within the photoresist and upon the semiconductor wafer within one or more active regions of the semiconductor wafer.

In another embodiment of the present invention, a semiconductor wafer fabrication method includes: applying a photoresist upon a semiconductor wafer, forming a nonstick seal upon the photoresist within a nonstick region of the semiconductor wafer, and forming plating structures within one or more active regions of the semiconductor wafer the semiconductor wafer adjacent to the nonstick region.

These and other embodiments, features, aspects, and advantages will become better understood with reference to the following description, appended claims, and accompanying drawings.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a wafer that has various regions, in accordance with various embodiments of the present invention.

FIG. 2A-FIG. 2D depict cross section views of a semiconductor structure at intermediate stages of semiconductor device fabrication, in accordance with various embodiments of the present invention.

FIG. 2E depicts a detailed view of exemplary perimeter seal regions, in accordance with various embodiments of the present invention.

FIG. 3A-FIG. 3D depict cross section views of a semiconductor structure at intermediate stages of semiconductor device fabrication, in accordance with various embodiments of the present invention.

FIG. 3E depicts a detailed view of exemplary perimeter seal regions, in accordance with various embodiments of the present invention.

FIG. 4A-FIG. 4C depict cross section views of a semiconductor structure at intermediate stages of semiconductor device fabrication, in accordance with various embodiments of the present invention.

FIG. 4D depicts a detailed view of exemplary perimeter seal regions, in accordance with various embodiments of the present invention.

FIG. 5A-FIG. 5C depict cross section views of a semiconductor structure at intermediate stages of semiconductor device fabrication, in accordance with various embodiments of the present invention.

FIG. 5D depicts a detailed view of exemplary perimeter seal regions, in accordance with various embodiments of the present invention.

FIG. 6A-FIG. 6C depict cross section views of a semiconductor structure at intermediate stages of semiconductor device fabrication, in accordance with various embodiments of the present invention.

FIG. 6D depicts a detailed view of exemplary perimeter seal regions, in accordance with various embodiments of the present invention.

FIG. 7A-FIG. 7C depict cross section views of a semiconductor structure at intermediate stages of semiconductor device fabrication, in accordance with various embodiments of the present invention.

FIG. 7D depicts a detailed view of exemplary perimeter seal regions, in accordance with various embodiments of the present invention.

FIG. 8-FIG. 11 depict exemplary semiconductor device fabrication process flow methods, in accordance with various embodiments of the present invention.

FIG. 12 depicts a flow diagram of a design process used in semiconductor design, manufacture, and/or test, in accordance with various embodiments of the present invention.

The drawings are not necessarily to scale. The drawings are merely schematic representations, not intended to portray specific parameters of the invention. The drawings are intended to depict only exemplary embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. These exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

Embodiments of invention generally relate to semiconductor devices, such as a wafer utilized in the production of a semiconductor chip (chip). The wafer may include a layer of semiconductor material, such as a silicon crystal, used in the fabrication of integrated circuits and other microdevices. The wafer typically serves as the substrate for microelectronic devices built in and over the wafer and undergoes many microfabrication process steps such as doping or ion implantation, etching, deposition of various materials, and photolithographic patterning. The individual microcircuits may be separated and packaged resulting in a chip.

The chip may be planar device and may comprise planar electrodes in parallel planes, made by alternate diffusion of p- and n-type impurities into the semiconductor substrate of the chip. Alternatively, the chip may be a FinFET type device and may comprise a plurality of fins formed from or upon the semiconductor substrate and a gate covering a portion of the fins. The portion of the fins covered by the gate may serve as a channel region of the device. Portions of the fins may also extend out from under the gate and may serve as source and drain regions of the device.

Referring now to the FIGs, wherein like components are labeled with like numerals, exemplary fabrication steps of forming a semiconductor structure such as a chip, integrated circuit, microdevice, etc. in accordance with embodiments of the present invention are shown, and will now be described in greater detail below. It should be noted that some of the FIGs depict various cross section views of the semiconductor structure. Furthermore, it should be noted that while this description may refer to components of the semiconductor structure in the singular tense, more than one component may be depicted throughout the figures and within the semiconductor structure. The specific number of components depicted in the FIGS and the cross section orientation was chosen to best illustrate the various embodiments described herein.

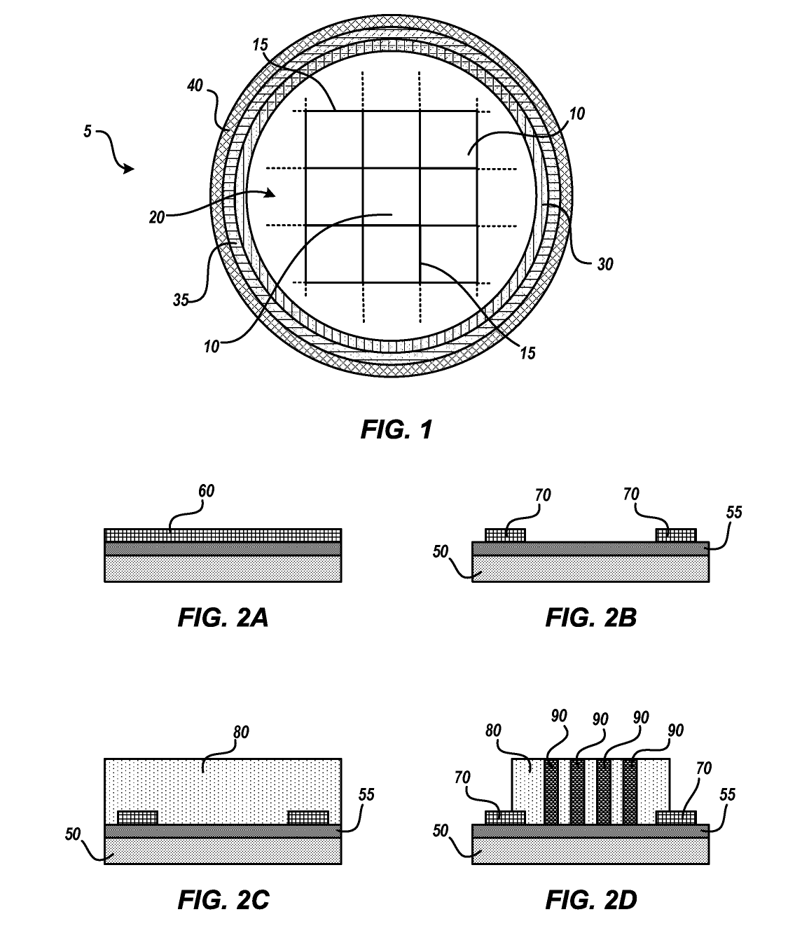

FIG. 1 depicts a wafer 5 with various regions, in accordance with various embodiments of the present invention. Wafer 5 may include a plurality of chips 10 separated by kerfs 15. Each chip 10 may include an active region 20 wherein integrated circuit devices, microelectronic devices, etc. may be built using microfabrication process steps such as doping or ion implantation, etching, deposition of various materials, photolithographic patterning, electroplating, etc.

Wafer 5 may further comprise at least a seal perimeter nonstick region 35 that includes a nonstick electroplating tool sealing surface. In various embodiments, wafer 5 may also include a non-patterned perimeter region 30 that is a transition region between nonstick region 35 and active region 20. In such embodiments, the dual perimeter regions provide the nonstick sealing surface while at least allowing for robust photoresist alignment tolerances and electrodeposition plating in active regions 20. Wafer 5 may also includes a perimeter edge region 40 that is free of photoresist material where the electrodeposition tool electrically contacts wafer 5 to enable electrodeposition.

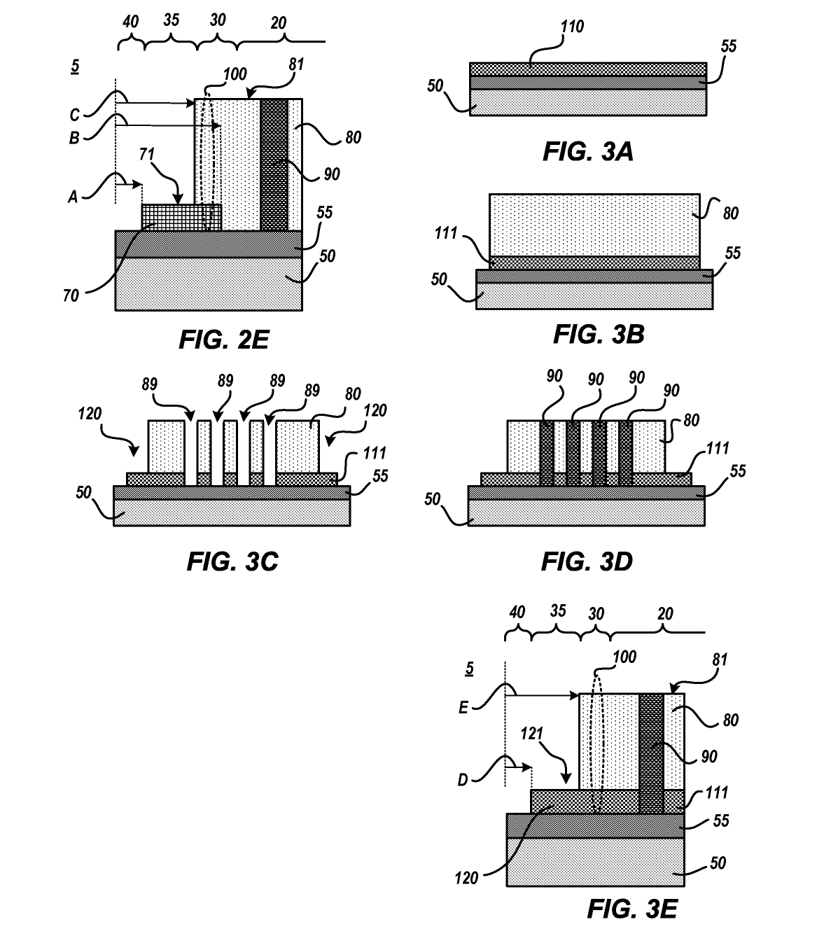

FIG. 2A depicts a cross section view of a semiconductor structure at intermediate stages of semiconductor device fabrication, in accordance with various embodiments of the present invention. At the present stage of fabrication, liquid photoresist layer 60 is formed upon a shorting layer 55 of a semiconductor substrate 50.

The shorting layer 55 is an electrically conductive layer that may be formed using a sputtering technique or other known metal deposition techniques. In embodiments, the shorting layer 55 may be, for example, copper or other conductive materials such as, for example, nickel, nickel alloys, copper alloys, etc. The shorting layer 55 may be multilayered and also include a seed layer which may be, for example, Ti, Ti Tungsten, or Ti Tungsten Chrome. The shorting layer 55 may be about 0.45 microns thick; although other dimensions are also contemplated by the present invention such as, for example, a range of about between 0.1 to 0.6 microns. In certain embodiments, shorting layer 55 is utilized as a shorting layer where the electrodeposition tool electrically contacts wafer 5 to enable electrodeposition.

The semiconductor substrate 50 may include, but is not limited to: any semiconducting material such conventional Si-containing materials, Germanium-containing materials, GaAs, InAs and other like semiconductors. Si-containing materials include, but are not limited to: Si, bulk Si, single crystal Si, polycrystalline Si, SiGe, amorphous Si, silicon-on-insulator substrates (SOI), SiGe-on-insulator (SGOI), annealed poly Si, and poly Si line structures. In various embodiments, substrate 50 may be, for example, a layered substrate (e.g. silicon on insulator) or a bulk substrate. The substrate 50 may include back end of the line micro devices, front end of the line micro devices, middle of the line micro devices, wiring layers, etc. formed within or thereupon.

Liquid photoresist layer 60 is a light-sensitive material applied as a liquid upon substrate 50 that may dry and be patterned forming a patterned coating upon substrate 50. Liquid photoresist layer 60 has nonstick propensities relative to e.g. dry photoresist. Such nonstick propensities include (a non exhaustive list): less thick compared than dry film photoresists (i.e. liquid photoresist layer 60 being e.g. 5 um to 20 um thick vs. a dry photoresist being e.g. 75 to 120 um thick); absence of large molecular weight polymers dispersed within smaller molecular weight polymers which would lead to greater likelihood to be selectively removed from wafer surface; require a lower temperature to drive off solvents.

Liquid photoresist layer 60 may be formed by precision spraying, roller coating, dip coating, spin coating, etc. Exemplary liquid photoresists can be either positive tone resists such as TCIR-ZR8800 PB manufactured by Tokyo Ohka Kogyo America, Inc. or negative tone resists such as JSR THB 126N manufactured by JSR Micro, Inc., Poly(methyl methacrylate) (PMMA), Poly(methyl glutarimide) (PMGI), Phenol formaldehyde resin (DNQ/Novolac), etc. The liquid photoresist layer 60 may have a thickness ranging from about 2 um to about 40 um, although a thickness less than 2 um and greater than 40 um have been contemplated. In one embodiment, liquid photoresist layer 60 may be about 5 um to 20 um thick. Generally, photoresist layer 60 may be formed by other known or additional techniques than those described without deviating from the spirit of those embodiments herein claimed.

FIG. 2B depicts a cross section view of a semiconductor structure at intermediate stages of semiconductor device fabrication, in accordance with various embodiments of the present invention. At the present stage of fabrication, nonstick seal 70 is formed upon the shorting layer 55 of semiconductor substrate 50.

In certain embodiments, a pattern may be formed in the photoresist layer 60 by e.g. exposing portions of the photoresist layer 60 to radiation. Once the patterning of the photoresist is completed, portions of the photoresist layer 60 may be retained and portions of photoresist layer 60 may be removed. The portions that are removed may reveal the underlying shorting layer 55. In certain embodiments, those portions of photoresist layer 60 that are retained to form nonstick seal 70. In other embodiments, rather than forming nonstick seal 70 from the photoresist layer 60, nonstick seal 70 may be selectively deposited or formed upon shorting layer 55. Nonstick seal 70 generally has nonstick propensities similar to those of photoresist layer 60 described herein. Nonstick seal 70 is formed along the perimeter of wafer 5 and may be formed within the nonstick region 35 of wafer 5. In certain embodiments, nonstick seal 70 is formed within the nonstick region 35 and non-patterned perimeter region 30 of wafer 5. In certain embodiments, nonstick seal 70 forms a concentric perimeter ring upon wafer 5. In embodiments, nonstick seal 70 separates perimeter edge region 40 from one or more active regions 20.

FIG. 2C depicts a cross section view of a semiconductor structure at intermediate stages of semiconductor device fabrication, in accordance with various embodiments of the present invention. At the present stage of fabrication, plating photoresist layer 80 is formed upon the shoring layer 55 of semiconductor substrate 50 surrounding nonstick seal 70.

Plating photoresist layer 80 is a dry photoresist that may be a semi-solid film coated, laminated, etc. upon semiconductor substrate 50. In certain embodiments, plating photoresist layer 80 includes plating propensities. For example, plating photoresist layer 80 is of sufficient thickness to form desired plating structures—in some implementations, plating within an active region 20 may require thick plating processes. As such, plating photoresist layer 80 may be chosen to be of a material and a thickness to satisfy such requirements.

Exemplary dry photoresists are Asahi CX8040, Asahi CXA240, Riston photoresists, WBR photoresists. The plating photoresist layer 80 may have a thickness ranging from about 40 um to about 500 um, although a thickness less than 40 um and greater than 500 um have been contemplated. In one embodiment, plating photoresist layer 80 may be about 150 um to 175 um thick. Generally, plating photoresist layer 80 may be formed by other known or additional techniques than those described without deviating from the spirit of those embodiments herein claimed.

In various embodiments, a mask (not shown) may be formed upon plating photoresist layer 80 in nonstick region 35 and/or non-patterned perimeter region 30 of wafer 5 prior to exposing photoresist layer 80. The mask protects the underlying nonstick seal 70 from cross linking with photoresist layer 80 to maintain the nonstick propensities of nonstick seal 70.

FIG. 2D depicts a cross section view of a semiconductor structure at intermediate stages of semiconductor device fabrication, in accordance with various embodiments of the present invention. At the present stage of fabrication, plating structures 90 are formed.

Plating structures 90 may be formed generally with photolithography and etch process steps. Specifically, a pattern is produced by exposing photoresist layer 80 in at least one active region 20 of wafer 5. The pattern may be subsequently developed utilizing a resist developer. Once the patterning of the photoresist layer 80 is completed, the sections of the underlying material covered by the photoresist are protected while the exposed regions of photoresist layer 80 are removed using a selective etching process. In certain embodiments, the removed portions of photoresist layer 80 form trenches.

In certain embodiments, edge portions of photoresist layer 80 may also be removed by photolithography and etch process steps to reveal at least a portion of nonstick seal 70. In other embodiments, the portion of nonstick seal 70 may be revealed by edge bead removal (EBR) techniques. For example, solvent may be dispensed on the edge of a rotating wafer 5 to remove the edge of photoresist layer 80. Alternatively, the edge of photoresist layer 80 may be removed by subjecting the resist on the outer edges of the wafer 5 to a broadband exposure know as wafer-edge exposure (WEE). In certain embodiments, an argon/oxygen, oxygen or nitrogen based ash may be performed to refresh photoresist layer 80 surfaces prior to plating. In various embodiments, the ash may remove the edge of photoresist layer 80 to reveal the portion of nonstick seal 70.

Plating structures 90 may be formed utilizing electrodeposition steps. Electrodeposition is a process in which, e.g. wafer 5 placed in the electroplating tool that contains a plating solution (e.g. plating bath, etc.). An electrical circuit is created when a negative terminal of a power supply is connected to wafer 5 (e.g. shorting layer 55, etc.) so as to form a cathode and a positive terminal of the power supply is connected to another metal in container so as to form an anode. The plating material is typically a stabilized metal specie (e.g., a metal ion) in the solution. During the plating process this metal specie is replenished with a soluble metal that forms the anode and/or can be added, directly to the solution (e.g., as a metal salt, metal concentrate). When an electrical current is passed through the circuit, metal ions in the solution take-up electrons at the wafer 5 and metal is formed on the wafer 5. In certain embodiments, the metal is formed within the trenches of photoresist layer 80 to form plating structures 90.

In various embodiments, plating structures 90 may be utilized as wiring or contacts to transfer electrical current. In certain embodiments, plating structures 90 are controlled collapse chip connection (C4) contact structures (e.g. pillars, etc.). Generally, plating structures 90 may be formed by other known or additional techniques than those described without deviating from the spirit of those embodiments herein claimed.

FIG. 2E depicts a detailed view of the perimeter seal regions of e.g. wafer 5 that includes an active region 20, a non-patterned perimeter region 30, nonstick region 35, and edge region 40. Plating photoresist layer 80 and plating structures 90 may be formed within active region 20. A stacked seal 100 comprising a portion of plating photoresist layer 80 upon a portion of nonstick seal 70 may exist within non-patterned perimeter region 30. Another portion of nonstick seal 70 may exist within perimeter nonstick region 35. Stacked seal 100 may serve as a transitional structure between the nonstick seal 70 portion within nonstick region 35 and plating photoresist layer 80 within active region 20. Shorting layer 55 may be exposed or revealed within edge region 40.

In an specific preferred embodiments, the width of nonstick seal 70 (i.e. dimension B minus dimension A) may range from 2.0 mm to 3.0 mm, dimension A may range from 1.2 mm to 1.9 mm, dimension C may range from 1.75 mm to 2.75 mm, and the width of stacked seal 100 (i.e. dimension B minus dimension C) may range from 0.25 mm to 1.25 mm.

In various embodiments, a seal of the electroplating tool may physically seal against nonstick seal 70 upon the plating of wafer 5. The seal of the electroplating tool to the nonstick seal 70 prevents leaks, prevents plating on shorting layer 55, etc. When wafer 5 is removed from the electroplating tool nonstick seal 70 has a propensity to not transfer to the electroplating tool. In various embodiments, the seal of the electroplating tool does not physically contact plating photoresist layer 80.

In certain embodiments, a top surface 71 of nonstick seal 70 may be coplanar with a top surface 81 of plating photoresist layer 80. In other embodiments, as shown in FIG. 2E, the top surface 71 of nonstick seal 70 is below the top surface 81 of plating photoresist layer 80. In other words, plating photoresist layer 80 may have a greater thickness than nonstick seal 70 so that plating structures 90 may be formed to a desired geometry, height, etc.

FIG. 3A depicts a cross section view of a semiconductor structure at intermediate stages of semiconductor device fabrication, in accordance with various embodiments of the present invention. At the present stage of fabrication, dielectric layer 110 is formed upon shorting layer 55 of semiconductor substrate 50.

Dielectric layer 110 may include any of several dielectric materials, for example, oxides, nitrides and oxynitrides of silicon. The dielectric layer 110 may also include oxides, nitrides and oxynitrides of elements other than silicon. In addition, the dielectric layer 110 may include crystalline or non-crystalline dielectric material. Moreover, the dielectric layer 110 may be formed using any of several known methods, for example, thermal or plasma oxidation or nitridation methods, chemical vapor deposition methods, and physical vapor deposition methods. The dielectric layer 110 may have a thickness in the sub-micron range. In one embodiment, the dielectric layer 110 may have a thickness ranging from about 50 nm to about 150 nm. In certain embodiments, dielectric layer 110 is a non-electrically conductive organic material. Dielectric layer 110 has nonstick propensities relative to e.g. dry photoresist. Generally, dielectric layer 110 may be formed by other known or additional techniques than those described without deviating from the spirit of those embodiments herein claimed.

FIG. 3B depicts a cross section view of a semiconductor structure at intermediate stages of semiconductor device fabrication, in accordance with various embodiments of the present invention. At the present stage of fabrication, dry photo resist is formed and patterned upon dielectric portion 111.

In certain embodiments, dielectric portion 111 may be formed by, for example, utilizing photolithography and a wet etch, dry etch, or combination. More specifically, a pattern may be produced by applying a masking layer such as a photoresist or photoresist with an underlying hardmask, to the dielectric layer 110, exposing the photoresist to a pattern of radiation; and then developing the pattern into the photoresist utilizing a resist developer. Once the patterning of the photoresist is completed, the sections of dielectric layer 110 covered by the photoresist are protected while the exposed edge regions dielectric layer 110 are removed using a selective etching process that removes the unprotected regions. The retained portions of dielectric layer 110 may form dielectric portion 111. In embodiments, dielectric portion 111 may be removed by EBR techniques. For example, solvent may be dispensed on the edge of a rotating wafer 5. Alternatively, a ring of exposed photoresist is formed by subjecting the resist on the outer edges of the wafer 5 to a broadband WEE exposure. Generally, dielectric portion 111 may be formed by other known or additional techniques than those described without deviating from the spirit of those embodiments herein claimed.

Plating photoresist layer 80 may be formed upon dielectric portion 111. In various embodiments, a mask (not shown) may be formed upon plating photoresist layer 80 prior to exposing photoresist layer 80. The mask protects underlying portions of the photoresist layer 80 in order for portions of photoresist layer 80 to be retained (shown) while portions of photoresist layer 80 are removed. In certain embodiments, a single WEE process may remove edge material to form dielectric portion 111 and photoresist layer 80 (i.e. photoresist layer 80 may be deposted upon dielectric layer 110 and edges of both layers may be similarly removed, etc.). In certain embodiments, plating photoresist layer 80 as shown formed in FIG. 3B, etc. may be a positive photoresist.

FIG. 3C depicts a cross section view of a semiconductor structure at intermediate stages of semiconductor device fabrication, in accordance with various embodiments of the present invention. At the present stage of fabrication, seal portion 120 and trenches 89 are formed.

In certain embodiments, the edges of photoresist layer 80 may be further removed by e.g. etching techniques, EBR techniques, WEE techniques, etc. to expose the underlying dielectric portion 111. The exposed dielectric portion 111 may form seal portion 120. Seal portion 120 has nonstick propensities similar to those of photoresist layer 60 described herein (i.e. seal portion 120 is e.g. less tacky than photoresist layer 80, etc.). In certain embodiments, seal portion 120 is formed generally along the perimeter of wafer 5. In certain embodiments, seal portion 120 is formed in nonstick region 35 of wafer 5. In certain embodiments, seal portion 120 forms a concentric ring in the nonstick region 35 of wafer 5. In embodiments, seal portion 120 separates perimeter edge region 40 from active region 20 generally upon substrate 50.

Trenches 89 may be formed generally with photolithography and etch process steps. Specifically, a pattern is produced by exposing photoresist layer 80 and/or dielectric 111 in at least one active region 20 of wafer 5. The pattern may be subsequently developed utilizing a resist developer. Once the patterning of the photoresist layer 80 and/or dielectric 111 is completed, the sections of the underlying material covered by the photoresist are protected while the exposed regions of photoresist layer 80 and/or dielectric 111 are removed using a etching process. In certain embodiments, the removed portions of photoresist layer 80 and/or dielectric 111 form trenches 89. In certain embodiments a single etch operation removes segments of photoresist layer 80 and segments of dielectric 111 to form trenches 89. In other embodiments, a first etch removes segments of photoresist layer 80 and a second etch removes segments of dielectric 111 to form trenches 89. In certain embodiments, an argon/oxygen, oxygen or nitrogen based ash may be performed to refresh exposed photoresist layer 80 and dielectric 111 surfaces prior to plating.

FIG. 3D depicts a cross section view of a semiconductor structure at intermediate stages of semiconductor device fabrication, in accordance with various embodiments of the present invention. At the present stage of fabrication, plating structures 90 are formed. For example, plating structures 90 may be formed utilizing electrodeposition steps. Plating structures 90 may be formed within the trenches 89.

FIG. 3E depicts a detailed view of the perimeter seal regions of e.g. wafer 5 that includes an active region 20, a non-patterned perimeter region 30, nonstick region 35, and edge region 40. Plating photoresist layer 80 and plating structures 90 may be formed within active region 20. A stacked seal 100 comprising a portion of plating photoresist layer 80 upon dielectric 111 may exist within non-patterned perimeter region 30. Stacked seal 100 may serve as a transitional region between seal portion 120 within nonstick region 35 and active region 20. Shoring layer 55 may be exposed within edge region 40. In a specific embodiments, the width of seal portion 120 (i.e. dimension E minus dimension D) may range from 2.0 mm to 3.0 mm and dimension D may range from 1.2 mm to 1.9 mm.

In various embodiments, a seal of the electroplating tool may physically contact seal portion 120 upon the plating of wafer 5 to e.g. prevent leaks, prevent plating upon shorting layer 55 in edge region 40, etc. When wafer 5 is removed from the electroplating tool seal portion 120 has a propensity to not transfer to the electroplating tool. In various embodiments, the seal of the electroplating tool does not physically contact plating photoresist layer 80. In certain embodiments, the top surface 121 of seal portion 120 is below the top surface 81 of plating photoresist layer 80. In other words, plating photoresist layer 80 may have a thickness sufficient to form desired plating structures 90.

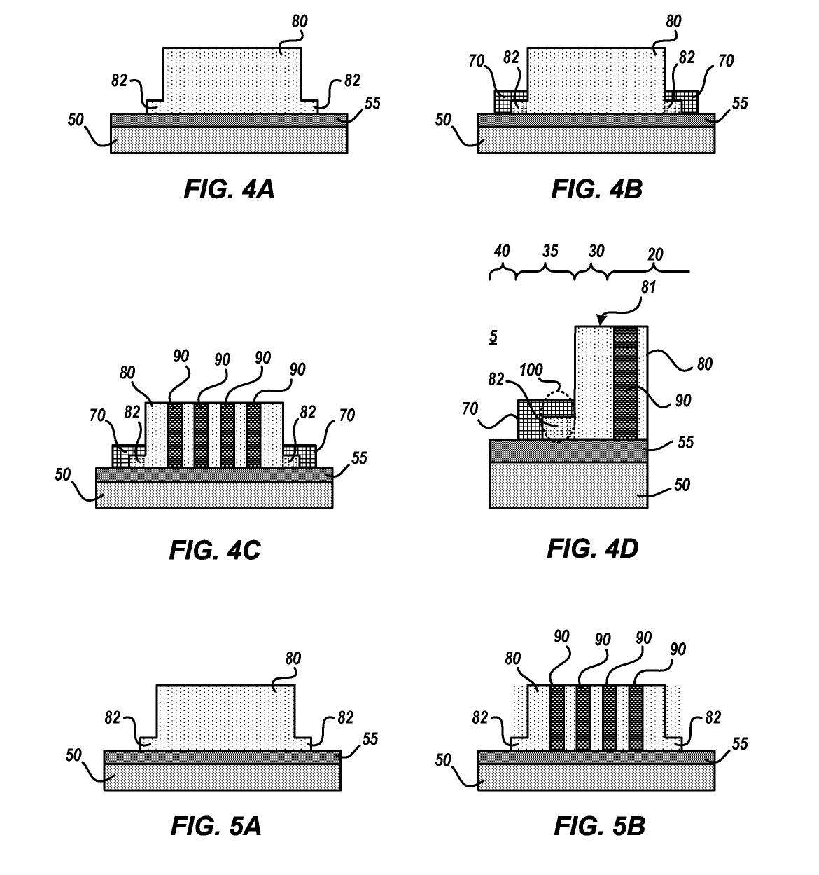

FIG. 4A depicts a cross section view of a semiconductor structure at intermediate stages of semiconductor device fabrication, in accordance with various embodiments of the present invention. At the present stage of fabrication, plating photoresist layer 80 is formed upon substrate 50. In various embodiments, a mask (not shown) may be formed upon plating photoresist layer 80 prior to exposing photoresist layer 80. The mask allow amounts of radiation exposure to photoresist layer 80. Multiple expose steps may be blitzed in order for portions of photoresist layer 80 to be retained (shown) while portions of photoresist layer 80 are removed. For example, a dual expose operation allows for a notch of photoresist layer 80 to be removed. The notch allows for the base of photoresist layer 80 to be greater than the top of photoresist layer 80 to form foot portions 82 at the base of photoresist layer 80. Generally, photoresist layer 80 with foot portions 82 may be formed by other known or additional techniques than those described without deviating from the spirit of those embodiments herein claimed.

FIG. 4B depicts a cross section view of a semiconductor structure at intermediate stages of semiconductor device fabrication, in accordance with various embodiments of the present invention. At the present stage of fabrication, nonstick seal 70 is formed upon the semiconductor substrate 50 adjacent to photoresist layer 80 surrounding foot portions 82. In certain embodiments, nonstick seal 70 may be formed from e.g. liquid photoresist layer 60 deposited upon the edge of wafer 5. A portion of the liquid photoresist layer 60 may be removed from the edge by e.g. EBR, WEE, etching, etc. to form nonstick seal 70. In other embodiments, rather than forming nonstick seal 70 from the photoresist layer 60, nonstick seal 70 may be selectively deposited or formed upon substrate 50 surrounding foot portions 82. In such embodiments, nonstick seal 70 has nonstick propensities similar to those of photoresist layer 60 described herein. In certain embodiments, nonstick seal 70 surrounding foot portion 82 is formed generally along the perimeter of wafer 5. Generally, nonstick seal 70 surrounding foot portion 82 may be formed by other known or additional techniques than those described without deviating from the spirit of those embodiments herein claimed.

FIG. 4C depicts a cross section view of a semiconductor structure at intermediate stages of semiconductor device fabrication, in accordance with various embodiments of the present invention. At the present stage of fabrication, plating structures 90 are formed within photoresist layer 80 upon the semiconductor substrate 50.

FIG. 4D depicts a detailed view of the perimeter seal regions of e.g. wafer 5 that includes active region 20, non-patterned perimeter region 30, nonstick region 35, and edge region 40. Plating photoresist layer 80 and plating structures 90 may be formed within active region 20. A stacked seal 100 comprising nonstick seal 70 surrounding foot portion 82 of plating photoresist layer may exist within nonstick region 35. A portion of plating photoresist layer 80 in non-patterned region 30 may serve as a transitional structure between nonstick seal 70 within nonstick region 35 and plating photoresist layer 80 within active region 20. Shorting layer 55 of substrate 50 may be exposed within edge region 40. In certain embodiments, a top surface 71 of nonstick seal 70 may be coplanar with a top surface 81 of plating photoresist layer 80. In other embodiments, as shown in FIG. 4D, the top surface 71 of nonstick seal 70 is below the top surface 81 of plating photoresist layer 80. In other words, plating photoresist layer 80 may have a greater thickness than nonstick seal 70 so that plating structures 90 may be formed to a desired geometry, height, etc.

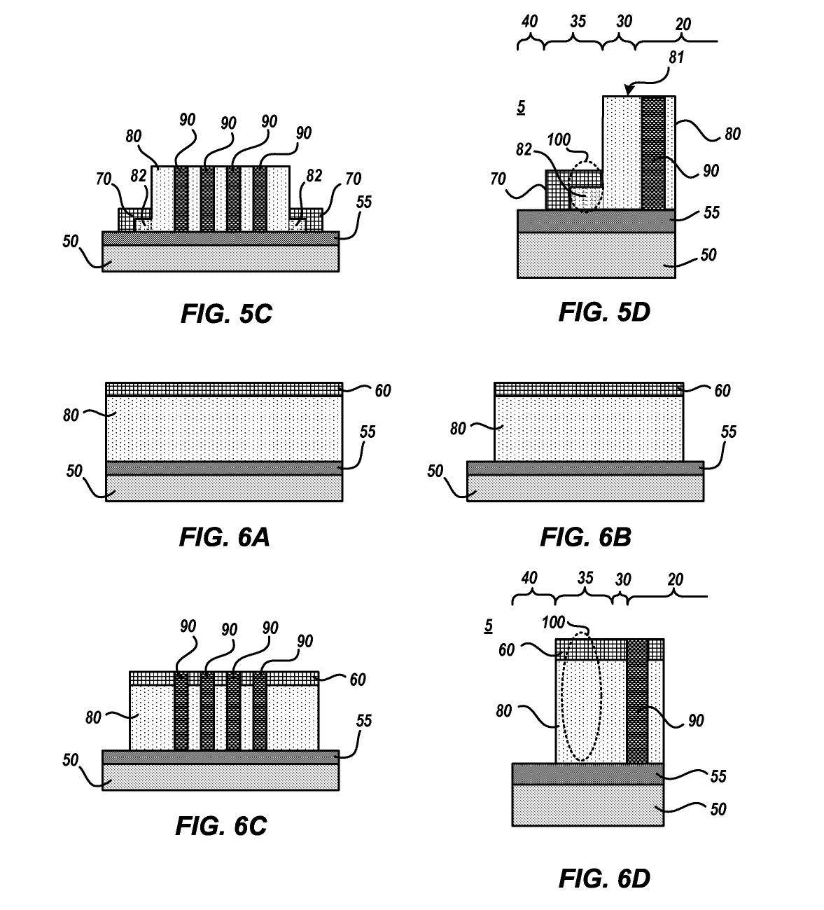

FIG. 5A depicts a cross section view of a semiconductor structure at intermediate stages of semiconductor device fabrication, in accordance with various embodiments of the present invention. At the present stage of fabrication, plating photoresist layer 80 having foot portion 82 is formed upon substrate 50.

FIG. 5B depicts a cross section view of a semiconductor structure at intermediate stages of semiconductor device fabrication, in accordance with various embodiments of the present invention. At the present stage of fabrication, plating structures 90 are formed within photoresist layer 80 upon the semiconductor substrate 50.

FIG. 5C depicts a cross section view of a semiconductor structure at intermediate stages of semiconductor device fabrication, in accordance with various embodiments of the present invention. At the present stage of fabrication, nonstick seal 70 is formed upon the semiconductor substrate 50 adjacent to photoresist layer 80 surrounding foot portions 82. In the present embodiment, formation of nonstick seal 70 subsequent to plating statures 90 may require a photoresist develop stage associated with the formation of nonstick seal 70. A mask may be formed upon e.g. photoresist layer 80 to protect the underlying material during such photoresist development associated with nonstick seal 70 formation. FIG. 5D depicts a detailed view of the perimeter seal regions of e.g. wafer 5 that includes active region 20, non-patterned perimeter region 30, nonstick region 35, and edge region 40.

FIG. 6A depicts a cross section view of a semiconductor structure at intermediate stages of semiconductor device fabrication, in accordance with various embodiments of the present invention. At the present stage of fabrication, plating photoresist layer 80 is formed upon shorting layer 55 of the semiconductor substrate 50 and liquid resist layer 60 is formed upon plating photoresist layer 80.

FIG. 6B depicts a cross section view of a semiconductor structure at intermediate stages of semiconductor device fabrication, in accordance with various embodiments of the present invention. At the present stage of fabrication, edges of plating photoresist layer 80 and edges of liquid resist layer 60 are removed. For example, edges of plating photoresist layer 80 and edges of liquid resist layer 60 may be removed utilizing photolithography and a wet etch, dry etch, or combination, utilizing EBR techniques, WEE techniques, ashing, etc.

FIG. 6C depicts a cross section view of a semiconductor structure at intermediate stages of semiconductor device fabrication, in accordance with various embodiments of the present invention. At the present stage of fabrication, trenches may be formed within photoresist layer 80 and liquid resist layer 60 and plating structures 90 may be formed utilizing electrodeposition steps.

FIG. 6D depicts a detailed view of the perimeter seal regions of e.g. wafer 5 that includes active region 20, non-patterned perimeter region 30, nonstick region 35, and edge region 40. Plating structures 90 may be formed within active region 20. A stacked seal 100 comprising a portion of liquid photoresist 60 upon a portion of photoresist layer 80 may exist within nonstick region 35. A portion of liquid photoresist 60 upon a portion of plating photoresist layer 80 in non-patterned region 30 may serve as a transitional structure between liquid photoresist 60 within nonstick region 35 and active region 20. Shorting layer 55 of substrate 50 may be exposed within edge region 40. In various embodiments, a seal of the electroplating tool may physically contact liquid photoresist 60 within nonstick region 35 of wafer 5 to e.g. prevent leaks, prevent plating upon shorting layer 55 in edge region 40, etc. When wafer 5 is removed from the electroplating tool, liquid photoresist 60 within nonstick region 35 has a propensity to not transfer to the electroplating tool.

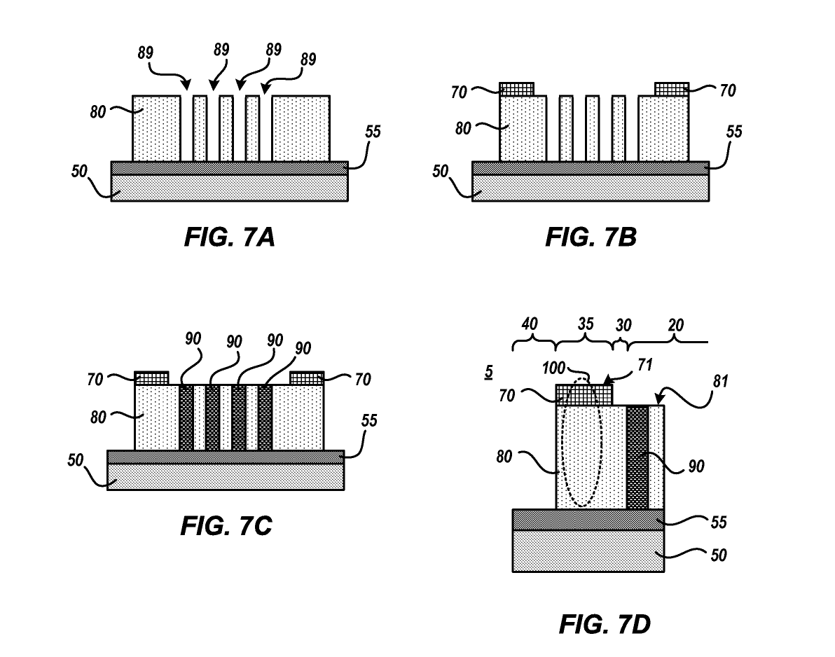

FIG. 7A depicts a cross section view of a semiconductor structure at intermediate stages of semiconductor device fabrication, in accordance with various embodiments of the present invention. At the present stage of fabrication, plating photoresist layer 80 is formed upon shorting layer 55 of semiconductor substrate 50. Further, at the present stage of fabrication, edges of photoresist layer 80 may be removed utilizing photolithography and a wet etch, dry etch, or combination, utilizing EBR techniques, WEE techniques, ashing, etc. Even further, at the present stage of fabrication, trenches 89 may be formed within photoresist layer 80 revealing portions of the underlying shorting layer 55.

FIG. 7B depicts a cross section view of a semiconductor structure at intermediate stages of semiconductor device fabrication, in accordance with various embodiments of the present invention. At the present stage of fabrication, nonstick seal 70 is formed upon the perimeter of photoresist layer 80.

FIG. 7C depicts a cross section view of a semiconductor structure at intermediate stages of semiconductor device fabrication, in accordance with various embodiments of the present invention. At the present stage of fabrication, plating structures 90 may be formed utilizing electrodeposition steps.

FIG. 7D depicts a detailed view of the perimeter seal regions of e.g. wafer 5 that includes active region 20, non-patterned perimeter region 30, nonstick region 35, and edge region 40. Photoresist layer 80 and plating structures 90 may be formed within active region 20. A stacked seal 100 comprising nonstick seal 70 upon a portion of photoresist layer 80 may exist within nonstick region 35. A portion of plating photoresist layer 80 in non-patterned region 30 may serve as a transitional structure between nonstick region 35 and active region 20. Shorting layer 55 of substrate 50 may be exposed within edge region 40. In various embodiments, a seal of the electroplating tool may physically contact nonstick seal 70 within nonstick region 35 of wafer 5 to e.g. prevent leaks, prevent plating upon shorting layer 55 in edge region 40, etc. When wafer 5 is removed from the electroplating tool, nonstick seal 70 within nonstick region 35 has a propensity to not transfer to the electroplating tool. In certain embodiments the top surface 71 of nonstick seal 70 is above the top surface 81 of photoresist layer 80, as is shown in FIG. 7D.

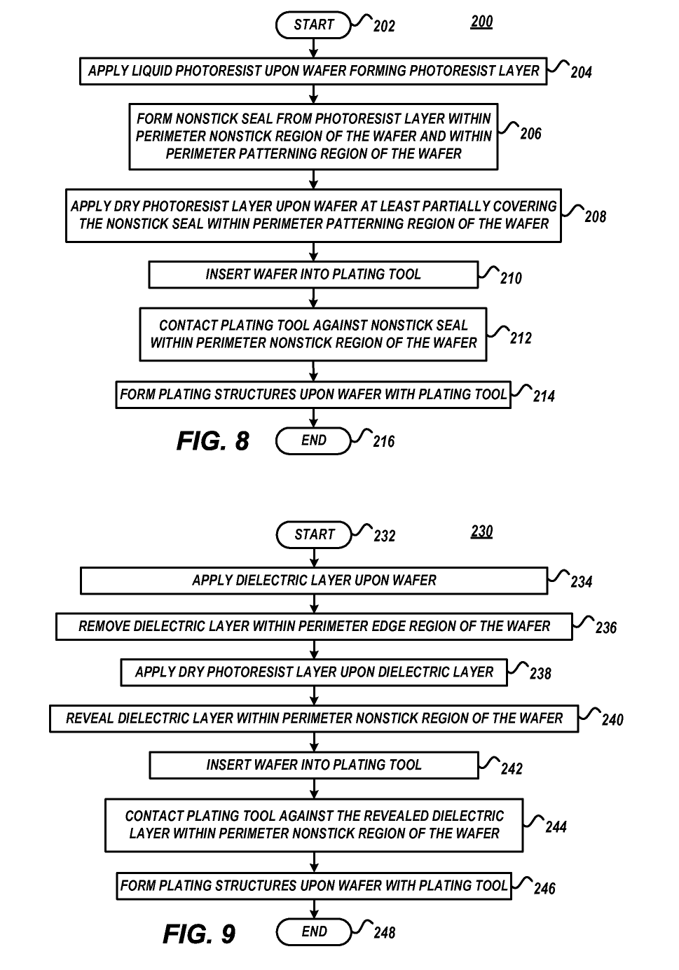

FIG. 8 depicts an exemplary semiconductor device fabrication process flow method 200, in accordance with various embodiments of the present invention. Method 200 begins at block 202 by applying liquid photo resist upon wafer 5 (block 204). For example, the liquid photo resist may be formed upon wafer 5. The liquid photoresist dries and forms a photoresist layer 60 that may be patterned. The photoresist layer 60 has nonstick propensities relative to e.g. dry photoresist. An exemplary depiction of one or more flow processes of block 204 is shown in FIG. 2A.

Method 200 may continue with forming a nonstick seal 70 from the photoresist layer 60 within the wafer's perimeter nonstick region 35 and within the non-patterned perimeter region 30 (block 206). For example, portions of the photoresist layer 60 may be retained and portions of photoresist layer 60 may be removed. The portions that are removed may expose the underlying substrate 50. In certain embodiments, those portions of photoresist layer 60 that are retained form nonstick seal 70. Nonstick seal 70 may form a concentric ring in the nonstick region 35 of wafer 5. Nonstick seal 70 may separate the wafer's perimeter edge region 40 from one or more active regions 20. An exemplary depiction of one or more flow processes of block 206 is shown in FIG. 2B.

Method 200 may continue with applying dry photoresist layer 80 upon wafer 5 at least partially covering nonstick seal 70 within the wafer's perimeter non-pattered region 30 (block 208). In various embodiments, plating photoresist layer 80 is of sufficient thickness to form desired plating structures 90. In various embodiments, a stacked seal 100 is formed from a portion of plating photoresist layer 80 and a portion of the nonstick seal 70 within non-patterned perimeter region 30. Stacked seal 100 may serve as a transitional region between nonstick seal 70 within nonstick region 35 and one or more active regions 20 of wafer 5. An exemplary depiction of one or more flow processes of block 208 is shown in FIG. 2C.

Method 200 may continue with inserting wafer 5 into a plating tool (block 210), such as an electrodeposition tool. In various embodiments, a seal of the electroplating tool may physically contact nonstick seal 70 within the nonstick region 35 of wafer 5 (block 212) to e.g. prevent leaks, prevent the plating of shorting layer 55 in region 40, etc. When wafer 5 is removed from the electroplating tool nonstick seal 70 has a propensity to not transfer to the electroplating tool. In various embodiments, the seal of the electroplating tool does not physically contact plating photoresist layer 80.

Method 200 may continue with forming plating structures 90 upon wafer 5 with the plating tool (block 214). For example, a pattern is produced by exposing photoresist layer 80 in one or more active regions 20 of wafer 5 and then developing the pattern utilizing a resist developer. Once the patterning of the photoresist layer 80 is completed, the sections of substrate 50 covered by the photoresist are protected while the exposed regions of photoresist layer 80 are removed using a selective etching process. In certain embodiments, the removed portions of photoresist layer 80 form trenches. Plating structures 90 may be further formed utilizing electrodeposition steps. For example, electrically conductive material such as a metal may be formed within trenches of photoresist layer 80. In certain embodiments, plating structures 90 are controlled collapse chip connection (C4) contact structures (e.g. pillars, etc.). In various embodiments, a mask may be formed upon wafer 5 in nonstick region 35 prior to exposing photoresist layer 80. The mask protects the underlying nonstick seal 70 from cross linking with photoresist layer 80 to maintain the nonstick propensities of nonstick seal 70. An exemplary depiction of one or more flow processes of block 214 is shown in FIG. 2D. Method 200 may end at block 216.

FIG. 9 depicts an exemplary semiconductor device fabrication process flow method 230, in accordance with various embodiments of the present invention. Method 230 begins at block 232 by applying a dielectric layer 110 upon wafer 5 (block 234). For example, the dielectric layer 110 may be formed upon a substrate of the wafer 5. The dielectric layer 110 has nonstick propensities relative to e.g. dry photoresist. In certain embodiments, dielectric layer 110 is a non-electrically conductive organic material. An exemplary depiction of one or more flow processes of block 234 is shown in FIG. 3A.

Method 230 may continue by removing edge portions of dielectric layer 110 within the perimeter edge region 40 of wafer 5 (block 236). For example, dielectric portion 111 may be formed. Edge portions of dielectric layer 110 may be removed by e.g. etching, EBR, WEE, etc. An exemplary depiction of one or more flow processes of block 236 is shown in FIG. 3B.

Method 230 may continue by applying dry photoresist layer 80 upon the dielectric portion 111 (block 238). In various embodiments, a stacked seal 100 is formed from a portion of plating photoresist layer 80 and a portion the dielectric layer within non-patterned perimeter region 30. Stacked seal 100 may serve as a transitional region between the revealed dielectric layer within nonstick region 35 and one or more active regions 20 of wafer 5. An exemplary depiction of one or more flow processes of block 236 is shown in FIG. 3C.

Method 230 may continue by revealing the dielectric 111 within the wafer 5 perimeter nonstick region 35 (block 240). For example, seal portion 120 may be formed by removing edges of photoresist layer 80 by e.g. etching techniques, EBR techniques, WEE techniques, etc. to expose the underlying dielectric portion 111. Seal portion 120 has nonstick propensities similar to those of photoresist layer 60 described herein (i.e. seal portion 120 is e.g. less tacky than photoresist layer 80, etc.). In certain embodiments, seal portion 120 is formed generally along the perimeter of wafer 5. In certain embodiments, seal portion 120 forms a concentric ring in the nonstick region 35 of wafer 5. In embodiments, seal portion 120 separates wafer 5 perimeter edge region 40 from active region 20. An exemplary depiction of one or more flow processes of block 240 is shown in FIG. 3D.

Method 230 may continue with inserting wafer 5 into a plating tool (block 242), such as an electrodeposition tool. In various embodiments, the seal of the electroplating tool may physically seal against the revealed dielectric layer (e.g. seal portion 120, etc.) within the nonstick region 35 of wafer 5 (block 244). When wafer 5 is removed from the electroplating tool revealed dielectric layer has a propensity to not transfer to the electroplating tool. In various embodiments, the seal of the electroplating tool does not physically contact plating photoresist layer 80.

Method 230 may continue with forming plating structures 90 upon wafer 5 with the plating tool (block 246). For example, a pattern is produced by exposing photoresist layer 80 in one or more active regions 20 of wafer 5 and then developing the pattern utilizing a resist developer. Once the patterning of the photoresist layer 80 is completed, the sections of substrate 50 covered by the photoresist are protected while the exposed regions of photoresist layer 80 are removed using a selective etching process. In certain embodiments, the removed portions of photoresist layer 80 form trenches. Plating structures 90 may be further formed utilizing electrodeposition steps. For example, electrically conductive material such as a metal may be formed within trenches of photoresist layer 80. In certain embodiments, plating structures 90 are controlled collapse chip connection (C4) contact structures (e.g. pillars, etc.). An exemplary depiction of one or more flow processes of block 246 is shown in FIG. 3D. Method 230 may end at block 248.

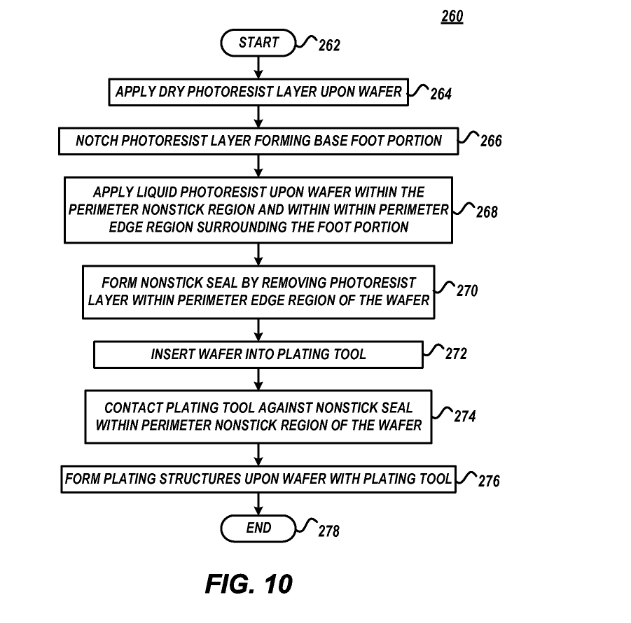

FIG. 10 depicts an exemplary semiconductor device fabrication process flow method 260, in accordance with various embodiments of the present invention. Method 260 begins at block 262 by applying dry photoresist layer 80 upon wafer 5 (block 264) and continues by notching photoresist layer 80 forming base foot portions 82 (block 266). For example, dual exposures of photoresist layer 80 form the notch along the edge of photoresist layer 80. The notch allows for the base of photoresist layer 80 to be greater than the top of photoresist layer 80 to form foot portions 82 at the base of photoresist layer 80. In various embodiments, a stacked seal 100 is formed by the foot portions 82 of plating photoresist layer 80 and a portion of the nonstick seal 70 within nonstick region 35. Stacked seal 100 may serve as a transitional region between perimeter edge region 40 and one or more active regions 20 of wafer 5. An exemplary depiction of one or more flow processes of blocks 264 and 266 are shown in FIG. 4A or FIG. 5A.

Method 260 may continue by applying liquid photoresist upon wafer 5 within the perimeter nonstick region 35 and within the perimeter edge region 40 surrounding foot portion 82 (block 268). The liquid photoresist dries and forms a photoresist layer 60 generally within perimeter nonstick region 35 and within the perimeter edge region 40. The photoresist layer 60 has nonstick propensities relative to e.g. dry photoresist. Method 260 may continue by forming nonstick seal 70 from the photoresist layer 60 by removing photoresist layer 60 from wafer 5 perimeter edge region 40(block 270). In other words, nonstick seal 70 may be formed within the wafer's perimeter nonstick region 35. A portion of the liquid photoresist layer 60 may be removed from the edge by e.g. EBR, WEE, etching, etc. to form nonstick seal 70. The portions of photoresist layer 60 may be removed to reveal the underlying substrate 50. An exemplary depiction of one or more flow processes of blocks 268 and 270 are shown in FIG. 4B and FIG. 5C.

Method 260 may continue with inserting wafer 5 into a plating tool (block 210), such as an electrodeposition tool. In various embodiments, a seal of the electroplating tool may physically contact nonstick seal 70 within the nonstick region 35 of wafer 5 (block 274) to e.g. prevent leaks or to prevent plating upon shorting layer 55 in region 40. When wafer 5 is removed from the electroplating tool nonstick seal 70 has a propensity to not transfer to the electroplating tool.

Method 260 may continue with forming plating structures 90 upon wafer 5 with the plating tool (block 276). For example, a pattern is produced by exposing photoresist layer 80 in one or more active regions 20 of wafer 5 and then developing the pattern utilizing a resist developer. Once the patterning of the photoresist layer 80 is completed, the sections of substrate 50 covered by the photoresist are protected while the exposed regions of photoresist layer 80 are removed using a selective etching process. In certain embodiments, the removed portions of photoresist layer 80 form trenches. Plating structures 90 may be further formed utilizing electrodeposition steps. In various embodiments, a mask may be formed upon wafer 5 in nonstick region 35 prior to exposing photoresist layer 80. The mask protects the underlying nonstick seal 70 from cross linking with photoresist layer 80 to maintain the nonstick propensities of nonstick seal 70. An exemplary depiction of one or more flow processes of block 276 is shown in FIG. 4C and FIG. 5B. Method 260 ends at block 278.

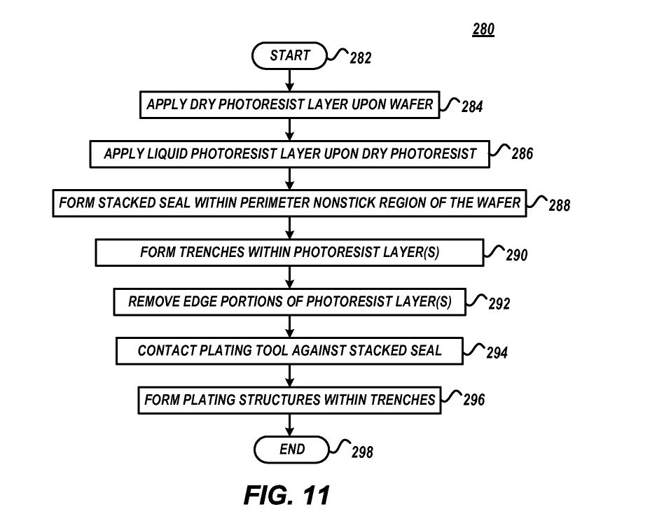

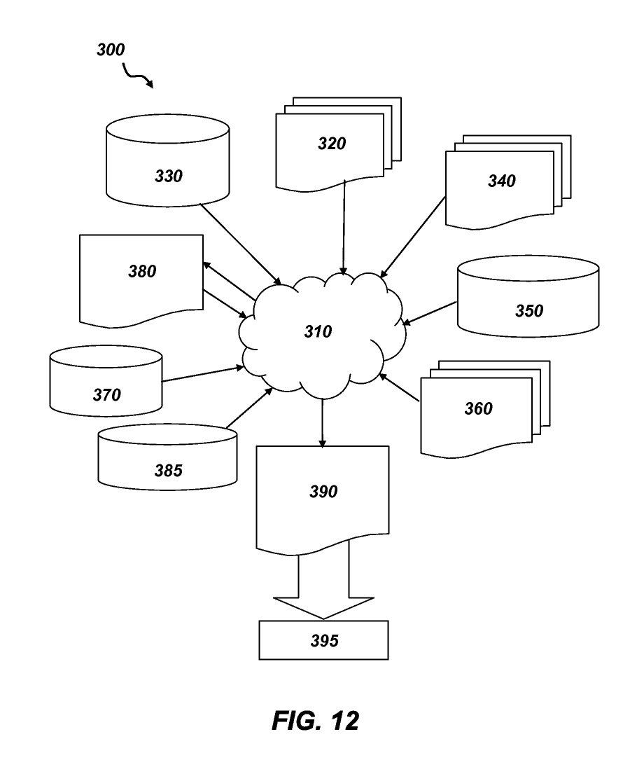

FIG. 11 depicts an exemplary semiconductor device fabrication process flow method 280, in accordance with various embodiments of the present invention. Method 280 begins at block 282 by applying dry photoresist layer 80 upon wafer 5 (block 284). For example, the photoresist layer 80 may be applied to the shorting layer 55 of substrate 50. An exemplary depiction of one or more flow processes of blocks 284 are shown in FIG. 6A or FIG. 7A.

Method 280 continues by applying liquid photoresist upon photoresist layer 80 (block 286). For example, liquid photoresist 60 may be blanket deposited upon photoresist layer 80 as shown in FIG. 6B. Further, liquid photoresist 60 may be e.g. selectively deposited or formed as nonstick seal 70 upon the perimeter of photoresist layer 80 as is shown in FIG. 7B.

Method 280 continues by forming stacked seal 100 within perimeter nonstick region 35 of wafer 5 (block 288). For example, stacked seal 100 comprises a portion of liquid photoresist 60 upon a portion of photoresist layer 80 within nonstick region 35 as is shown in FIG. 6D. Further, stacked seal 100 may comprise nonstick seal 70 upon a portion of photoresist layer 80 within nonstick region 35 as is shown in FIG. 7D.

Method 280 continues with forming trenches 89 within photoresist 80 and/or photoresist 60 exposing the underlying wafer 5 material (e.g. shorting layer 55, etc.) (block 290). For example, a pattern is produced by exposing photoresist layer 80 in one or more active regions 20 of wafer 5 and then developing the pattern utilizing a resist developer. Once the patterning of the photoresist layer 80 is completed, the sections of wafer 5 covered by the photoresist are protected while the exposed regions of photoresist layer 80 are removed using a selective etching process. In certain embodiments, the removed portions of photoresist layer 80 form trenches 89. An exemplary depiction of one or more flow processes of blocks 290 is shown in e.g. FIG. 7A. In certain embodiments the trenches 89 are formed within the photoresist layer 60 and within the underlying photoresist layer 80 as is shown in FIG. 6C.

Method 280 may continue by removing the perimeter edges of photoresist 80 and/or liquid photoresist 60 (block 292). For example, edge portions of photoresist 80 and portions of liquid photoresist layer 60 may be simultaneously or serially removed by e.g. EBR, WEE, etching, etc. as is exemplarily shown in FIG. 6B. The edge portions may be removed to reveal the underlying shorting layer 50 of substrate 50. In another example, edge portions of photoresist 80 may be removed prior to developing photoresist 80 to e.g. form trenches 89 as is exemplarily shown in FIG. 7A.

Method 280 may continue with sealing a electrodeposition tool against the stacked seal 100 to e.g. prevent leaks, prevent plating upon shorting layer 55, etc. (block 294). In various embodiments, a seal of the electroplating tool may physically contact nonstick seal 70 within the nonstick region 35 of wafer 5 (i.e. the embodiment shown in FIG. 7D). In other embodiments, a seal of the electroplating tool may contact a portion of the liquid photoresist layer 60 within the nonstick region 35 of wafer 5 (i.e. the embodiment shown in FIG. 6D). When wafer 5 is removed from the electroplating tool nonstick seal 70 and/or liquid photoresist layer 60 have a propensity to not transfer to the electroplating tool.

Method 260 may continue with forming plating structures 90 within trenches 89 with the plating tool (block 296). Plating structures 90 may be further formed utilizing electrodeposition steps. An exemplary depiction of one or more flow processes of block 296 is shown in FIG. 6C and FIG. 7C. Method 280 ends at block 298.

Referring now to FIG. 12, a block diagram of an exemplary design flow 300 used for example, in semiconductor integrated circuit (IC) logic design, simulation, test, layout, and/or manufacture is shown. Design flow 300 includes processes, machines and/or mechanisms for processing design structures or devices to generate logically or otherwise functionally equivalent representations of the structures and/or devices described above and shown in FIGS. 1-7.

The design structures processed and/or generated by design flow 300 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 300 may vary depending on the type of representation being designed. For example, a design flow 300 for building an application specific IC (ASIC) may differ from a design flow 300 for designing a standard component or from a design flow 300 for instantiating the design into a programmable array, for example a programmable gate array (PGA) or a field programmable gate array (FPGA) offered by Altera® Inc. or Xilinx® Inc.

FIG. 12 illustrates multiple such design structures including an input design structure 320 that is preferably processed by a design process 310. Design structure 320 may be a logical simulation design structure generated and processed by design process 310 to produce a logically equivalent functional representation of a hardware device. Design structure 320 may also or alternatively comprise data and/or program instructions that when processed by design process 310, generate a functional representation of the physical structure of a hardware device. Whether representing functional and/or structural design features, design structure 320 may be generated using electronic computer-aided design (ECAD) such as implemented by a core developer/designer.

When encoded on a machine-readable data transmission, gate array, or storage medium, design structure 320 may be accessed and processed by one or more hardware and/or software modules within design process 310 to simulate or otherwise functionally represent an electronic component, circuit, electronic or logic module, apparatus, device, structure, or system such as those shown in FIGS. 1-7. As such, design structure 320 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 310 preferably employs and incorporates hardware and/or software modules for synthesizing, translating, or otherwise processing a design/simulation functional equivalent of the components, circuits, devices, or structures shown FIGS. 1-7. to generate a Netlist 380 which may contain design structures such as design structure 320. Netlist 380 may comprise, for example, compiled or otherwise processed data structures representing a list of wires, discrete components, logic gates, control circuits, I/O devices, models, etc. that describes the connections to other elements and circuits in an integrated circuit design. Netlist 380 may be synthesized using an iterative process in which netlist 380 is resynthesized one or more times depending on design specifications and parameters for the device. As with other design structure types described herein, netlist 380 may be recorded on a machine-readable data storage medium or programmed into a programmable gate array. The storage medium may be a non-volatile storage medium such as a magnetic or optical disk drive, a programmable gate array, a compact flash, or other flash memory. Additionally, or in the alternative, the storage medium may be a system or cache memory, buffer space, or electrically or optically conductive devices in which data packets may be intermediately stored.

Design process 310 may include hardware and software modules for processing a variety of input data structure types including Netlist 380. Such data structure types may reside, for example, within library elements 330 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 340, characterization data 350, verification data 360, design rules 370, and test data files 385 which may include input test patterns, output test results, and other testing information. Design process 310 may further include, for example, standard mechanical design processes such as stress analysis, thermal analysis, mechanical event simulation, process simulation for operations such as casting, molding, and die press forming, etc.

One of ordinary skill in the art of mechanical design can appreciate the extent of possible mechanical design tools and applications used in design process 310 without deviating from the scope and spirit of the invention claimed herein. Design process 310 may also include modules for performing standard circuit design processes such as timing analysis, verification, design rule checking, place and route operations, etc.

Design process 310 employs and incorporates logic and physical design tools such as HDL compilers and simulation model build tools to process design structure 320 together with some or all of the depicted supporting data structures along with any additional mechanical design or data (if applicable), to generate a second design structure 390. Design structure 390 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures).

Similar to design structure 320, design structure 390 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-7. In one embodiment, design structure 390 may comprise a compiled, executable HDL simulation model that functionally simulates the devices shown in FIGS. 1-7.

Design structure 390 may also employ a data format used for the exchange of layout data of integrated circuits and/or symbolic data format (e.g. information stored in a GDSII (GDS2), GL1, OASIS, map files, or any other suitable format for storing such design data structures). Design structure 390 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-7. Design structure 390 may then proceed to a stage 395 where, for example, design structure 390: proceeds to tape-out, is released to manufacturing, is released to a mask house, is sent to another design house, is sent back to the customer, etc.

The accompanying figures and this description depicted and described embodiments of the present invention, and features and components thereof. Those skilled in the art will appreciate that any particular nomenclature used in this description was merely for convenience, and thus the invention should not be limited by the specific process identified and/or implied by such nomenclature. Therefore, it is desired that the embodiments described herein be considered in all respects as illustrative, not restrictive, and that reference be made to the appended claims for determining the scope of the invention.

The exemplary methods and techniques described herein may be used in the fabrication of integrated circuit chips. The resulting integrated circuit chips can be distributed by the fabricator in raw wafer form (i.e., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). The chip is then integrated with other chips, discrete circuit elements and/or other signal processing devices as part of either (a) an intermediate product, such as a motherboard, or (b) an end product. The end product can be any product that includes integrated circuit chips, ranging from toys and other low-end applications to advanced computer products having numerous components, such as a display, a keyboard or other input device and/or a central processor, as non-limiting examples.

References herein to terms such as “vertical”, “horizontal”, etc. are made by way of example, and not by way of limitation, to establish a frame of reference. The term “horizontal” as used herein is defined as a plane parallel to the conventional plane or surface of the substrate, regardless of the actual spatial orientation of the semiconductor substrate. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

The invention claimed is:

1. A semiconductor wafer fabrication method comprising:
forming a nonstick seal within a nonstick region and within a non-pattering region of a semiconductor wafer;
applying a photoresist upon the semiconductor wafer within one or more active regions and upon the nonstick seal within the non-pattering region, and;
forming plating structures within the photoresist within the one or more active regions of the semiconductor wafer.

2. The semiconductor wafer fabrication method of claim 1, wherein forming plating structures comprises:
inserting the semiconductor wafer into an electrodeposistion plating tool, and;
sealing the electrodeposistion tool against the nonstick seal.

3. The semiconductor wafer fabrication method of claim 1, wherein the plating structures are controlled collapse chip connection (C4) contact pillars.

4. The semiconductor wafer fabrication method of claim 1, further comprising:
forming a stacked seal comprising a portion of the nonstick seal and a portion of the photoresist.

5. The semiconductor wafer fabrication method of claim 4, wherein the stacked seal is a transitional structure of the semiconductor wafer between the nonstick region and one or more active regions.

6. The semiconductor wafer fabrication method of claim 1, wherein integrated circuits are formed within the one or more active regions of the semiconductor wafer.

7. The semiconductor wafer fabrication method of claim 1, wherein forming the nonstick seal further comprises:
depositing a liquid photoresist upon the semiconductor wafer.

8. A semiconductor wafer fabrication method comprising:
forming an organic dielectric upon a semiconductor wafer;
removing the organic dielectric within a perimeter edge region of the semiconductor wafer;
applying a photoresist upon the organic dielectric;
revealing the organic dielectric within a nonstick region of the semiconductor wafer, and;
forming plating structures within the photoresist and upon the semiconductor wafer within one or more active regions of the semiconductor wafer.

9. The semiconductor wafer fabrication method of claim 8, wherein forming plating structures comprises:
inserting the semiconductor wafer into an electrodeposistion plating tool, and;
sealing the electrodeposistion tool against the revealed organic dielectric.

10. The semiconductor wafer fabrication method of claim 8, wherein the plating structures are controlled collapse chip connection (C4) contact pillars.

11. The semiconductor wafer fabrication method of claim 8, further comprising:
forming a stacked seal comprising a portion of the revealed organic dielectric and a portion of the photoresist.

12. The semiconductor wafer fabrication method of claim 11, wherein the stacked seal is a transitional structure of the semiconductor wafer between the nonstick region and one or more active regions.

13. The semiconductor wafer fabrication method of claim 8, wherein integrated circuits are formed within the one or more active regions of the semiconductor wafer.

14. A semiconductor wafer fabrication method comprising:
applying a photoresist upon a semiconductor wafer;
forming a nonstick seal upon the photoresist within a nonstick region of the semiconductor wafer, and;
forming plating structures within one or more active regions of the semiconductor wafer the semiconductor wafer adjacent to the nonstick region.

15. The semiconductor wafer fabrication method of claim 14, wherein forming plating structures comprises:
inserting the semiconductor wafer into an electrodeposistion plating tool, and;
sealing the electrodeposistion tool against the nonstick seal.

16. The semiconductor wafer fabrication method of claim 14, wherein the plating structures are controlled collapse chip connection (C4) contact pillars.

17. The semiconductor wafer fabrication method of claim 14, further comprising:
forming a stacked seal within the nonstick region comprising a portion of the nonstick seal and a portion of the photoresist.

18. The semiconductor wafer fabrication method of claim 17, wherein the stacked seal is a transitional structure of the semiconductor wafer between a perimeter edge region of the semiconductor wafer and the one or more active regions.

19. The semiconductor wafer fabrication method of claim 14, wherein integrated circuits are formed within the one or more active regions of the semiconductor wafer.

20. The semiconductor wafer fabrication method of claim 14, wherein forming the nonstick seal further comprises:
depositing a liquid photoresist upon the photoresist.
